(19) United States
(12) Patent Application Publication
(10) Pub. No.: US 2004/0251977 A1
(43) Pub. Date: Dec. 16, 2004

(54) Low-current, area-efficient and flicker noise free bias CMOS voltage control oscillator

(76) Inventors: Abdellatif Bellaouar, Richardson, TX (US); See Taur Lee, Richardson, TX (US)

Correspondence Address: Ronald O. Neerings, Texas Instruments Incorporated, MS 3999, P.O. Box 655474, Dallas, TX, 75265, US

(21) Appl. No.: 10/810,095

(22) Filed: Mar. 26, 2004

Related U.S. Application Data
(60) Provisional application No. 60/458,859, filed on Jun. 12, 2003.

(51) Int. Cl. H03L 7/00

(52) U.S. Cl. 331/117 R

(57) ABSTRACT

A method of implementing a low-current, area-efficient and flicker noise free bias CMOS voltage control oscillator (VCO) 200 employs a resistor 202 as a current source to the VCO core. By eliminating the transistor current source as employed in conventional designs, the CMOS VCO 200 does not require any reference current source, and thus achieves at least a 10-20% current savings over that achievable using prior art techniques. Further, noise amplification issues from the reference current source do not exist since only a resistor 202 is used as a current source, yielding only resistor thermal noise. The method employed allows low supply pushing, an important factor to be considered in VCO designs.

### CLAIM TO PRIORITY OF PROVISIONAL APPLICATION

The application claims priority under 35 U.S.C. § 119(e)(1) of provisional application Ser. No. 60/458,859, attorney docket number TI-36131PS, entitled Low-Current, Area-Efficient and Flicker Noise Free Bias CMOS Voltage Control Oscillator, filed Mar. 28, 2003, by Abdellatif Bellaouar and See Taur Lee.

### BACKGROUND OF THE INVENTION

1. Field of the Invention

This invention relates generally to voltage control oscillators (VCO), and more particularly to a system and method for implementing a current bias to a VCO core via a resistor rather than a more conventional transistor.

2. Description of the Prior Art

Radio frequency systems-on-chip have a very bright future, especially if they are capable of providing a very low-cost solution. Such RF systems have however, posed tremendous design challenges, for example, in the design of VCOs, low-noise amplifiers and power amplifiers.

A significant effort has been devoted in the VCO art to the design of CMOS VCOs in order to replace bipolar circuits with low-cost CMOS solutions and maintain acceptable phase noise performance. Illustrated in FIG. 1 is one of the prior art differential CMOS VCO 100 solutions. It consists of transistors M1-M2 102, 104 and current source IB 106 as the current source to the VCO core, inductances L1-L2 108, 110 and capacitance C1 112 as the LC-tank circuit, and a cross-coupled differential transistor pair M3-M4 114, 116 that provides the negative resistance.

In a fully integrated CMOS VCO, the main sources of phase noise have been shown by B. Razavi, “Study of phase noise in CMOS oscillators,” IEEE J. Solid-State Circuits, vol. 31, pp. 331-343, March 1996, and H. Wang, “A 50 GHz VCO in 0.25 um CMOS,” ISSCC Digest of Technical Papers, pp. 372-373, February 2001, to be the thermal noise of the passive and active devices, flicker noise of the transistor and supply and substrate noise.

Numerous techniques have been proposed to reduce the thermal noise of passive devices. H. Jiang, et al., “Electromagnetically shielded high-Q CMOS-compatible copper inductors,” ISSCC Digest of Technical Papers, pp. 330-331, February 2000, for example, proposed a high-Q electromagnetically shielded inductor showing that it is possible to achieve an inductor Q higher than 30.

The two remaining noise sources then are attributable to the cross-coupled transistor pair M3-M4 noises and the bias current transistor noises. Efforts to push the phase noise of the CMOS VCO to even lower levels have shown the only noise sources that can be eliminated or reduced are the bias current transistor noises. An analysis by E. Hegazi, H. Sjoland, A. Abidi, “A filtering technique to lower oscillator phase noise,” ISSCC Digest of Technical Papers, pp 364-365, February 2001, showed that the commutating differential pair translates noise from the current source at frequencies around the second harmonics to the oscillation frequency and to the third harmonic and half of the translated noise at the fundamental frequency contributes phase noise. The authors also suggested that the differential cross-coupled pair upconverts the baseband noise in the current source into amplitude noise across the resonator. A filtering technique to lower the VCO phase noise has been proposed by these authors.

One of the drawbacks of the foregoing proposed technique is that more area is needed by the additional L-C noise filter. The present inventors believe that proper design of the current source using bigger size transistors can actually achieve a comparable phase noise. Another alternative is shown in FIG. 2, that shows additional filtering to reduce the noise contribution from the current source. Noises from the current source can be reduced; and thus phase noise at low frequency offset can be minimized simply by adding transistor M5 118.

Thus far, all the proposed or published techniques to push for lower VCO phase noise can only reduce or minimize the noises contributed from the current source. In view of the foregoing, it is highly desirable and advantageous to provide a technique for providing a flicker noise free current source to achieve a low VCO phase noise at low frequency offset.

### SUMMARY OF THE INVENTION

The present invention is directed to a system and method for implementing a low-current, area-efficient and flicker noise free bias CMOS voltage control oscillator. In contradistinction with prior art techniques, the present system and method do not require any L-C noise filter or use of huge transistor sizes to reduce the noise contributions from the current source. The CMOS VCO employs but a simple resistor as a bias current source with an optional capacitor (i.e., MOS transistor) to act as a filtering capacitor to stabilize the biasing voltage and to reduce the effect of junction capacitance variations from the cross-coupled transistor pair. Since the current source to the VCO core employs only a resistor, the only noise source is the thermal noise from the resistor. With proper design, low supply pushing can also be achieved. The CMOS VCO advantageously requires no reference current source, resulting in at least a 10-20% current saving over known techniques. Further, noise amplification from the reference current source is eliminated. A low noise reference current source is therefore not required in the present CMOS VCO. A programmable current source to the CMOS VCO can be easily obtained via adding resistors in parallel. Either one or two cross-coupled pairs can be used in association with the CMOS VCO. The simple current source allows a compact and area-efficient CMOS VCO.

According to one embodiment, a voltage control oscillator (VCO) comprises an L-C tank circuit; a negative resistance generator operational to oscillate at a frequency determined by the L-C tank circuit, the L-C tank circuit and the negative resistance generator together forming a VCO core; and a VCO core current source comprising at least one passive resistor, and devoid of capacitors, inductors and active components.

According to another embodiment, a voltage control oscillator (VCO) comprises a tuning circuit; a negative resistance generator operational to oscillate at a frequency determined by the tuning circuit, the tuning circuit and the negative resistance generator together forming a VCO core; and a VCO core current source comprising at least one passive resistor, and devoid of capacitors, inductors and active components, wherein the current source operates to provide a VCO bias current.

According to yet another embodiment of the present invention, a voltage control oscillator (VCO) comprises oscillating means for oscillating at a desired frequency; tuning means for controlling the desired frequency, the oscillating means and the tuning means together forming a VCO core; and biasing means for providing a VCO core bias current, wherein the biasing means is devoid of capacitors, inductors and active components.

According to still another embodiment of the present invention, a method of controlling a voltage control oscillator (VCO) phase noise comprises the steps of providing a VCO core; and generating a self-bias current for the VCO core via a resistor bias current source that is devoid of capacitors, inductors and active components.

### BRIEF DESCRIPTION OF THE DRAWINGS

Other aspects and features of the present invention and many of the attendant advantages of the present invention will be readily appreciated as the same become better understood by reference to the following detailed description when considered in connection with the accompanying drawings in which like reference numerals designate like parts throughout the figures thereof and wherein:

FIG. 1 is a schematic diagram illustrating a prior art differential CMOS voltage control oscillator;

FIG. 2 is a schematic diagram showing the prior art differential CMOS voltage control oscillator shown in FIG. 1 with additional filtering to reduce the noise contribution from the current source;

FIG. 3 is a schematic diagram illustrating a resistor bias CMOS VCO according to one embodiment of the present invention;

FIG. 4 is a schematic diagram illustrating a resistor bias CMOS VCO according to another embodiment of the present invention having CMOS cross-coupled pairs;

FIG. 5 is a schematic diagram illustrating a resistor bias CMOS VCO according to yet another embodiment of the present invention having an optional power down transistor; and

FIG. 6 is a schematic diagram illustrating a resistor bias CMOS VCO according to still another embodiment of the present invention having a programmable current source.

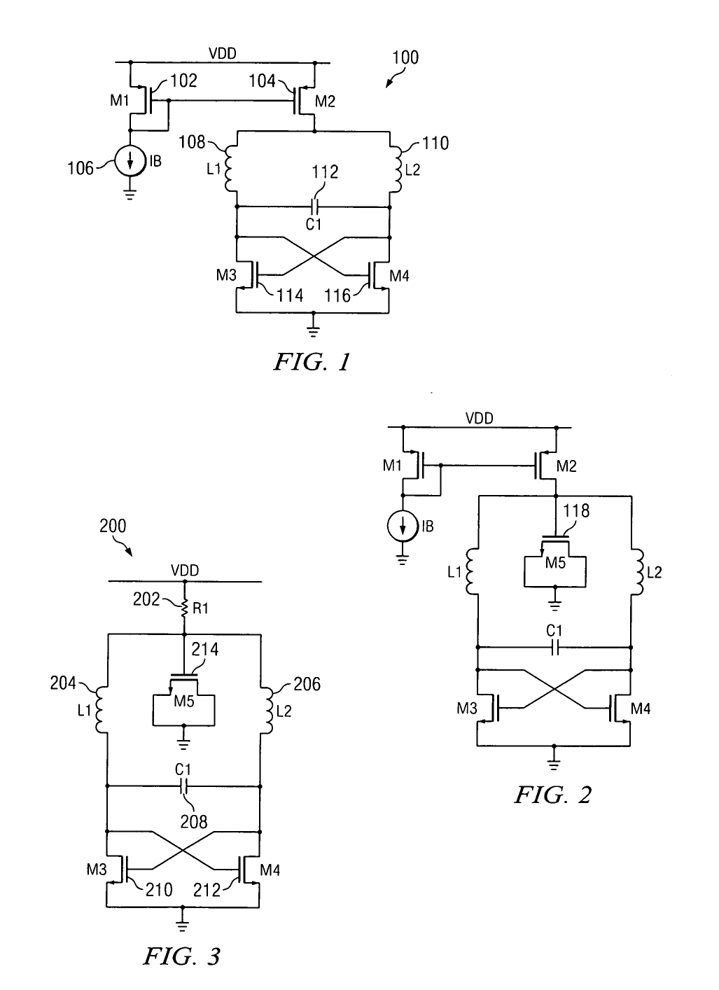

While the above-identified drawing figures set forth alternative embodiments, other embodiments of the present invention are also contemplated, as noted in the discussion. In all cases, this disclosure presents illustrated embodiments of the present invention by way of representation and not limitation. Numerous other modifications and embodiments can be devised by those skilled in the art which fall within the scope and spirit of the principles of this invention.

### DETAILED DESCRIPTION OF THE PREFERRED EMBODIMENTS

Low phase noise at low offset frequency has become a very important factor in the design of a VCO. Since a VCO consists of three major parts, namely the LC-tank, negative resistance generator and the current source, the only noise source that can be further minimized to implement a low phase noise oscillator is the current source as discussed herein before. FIG. 3 shows a schematic diagram illustrating the most preferred embodiment of the present CMOS VCO 200. It consists of a resistor R1 202 as the current source to the VCO core, inductances L1-L2 204, 206 and capacitor C1 208 that form the LC-tank, a cross-coupled CMOS pair M3-M4 210, 212 that provides the negative resistance and to maintain oscillation and transistor M5 214 that acts as a capacitor. A varactor can be added to tune the center frequency of the oscillator 200, which is not shown in FIG. 3. In operation, the center frequency is fixed by the differential inductances and capacitances. The amount of current required by the VCO core can be adjusted by changing the resistance of the resistor R1 202. Transistor M5 214 has been added to act as a capacitor and provides filtering to the noise from the power supply VDD. It also stabilizes the dc voltage and minimizes the effect of capacitance variation from the junction capacitance of the cross-coupled pair M3-M4 210, 212.

Another important factor to be considered in the design of a VCO is the effect of supply pushing, especially when the VCO is integrated with noisy circuits. A simple analysis on the frequency sensitivity to the power supply has been performed. Indirectly, the frequency sensitivity to the supply can be found by obtaining the current variation in the resistor 202 due to supply variation. The current in the bias resistor 202 can be expressed as

$$I = \frac{Vdd - Vgs}{R} \qquad ( 1 )$$

where I, Vdd, Vgs and R are the current through resistor R1 202, supply voltage, gate-to-source voltage of the cross-coupled pair 210, 212 and resistance of R1 202 respectively. The current through the cross-coupled transistors 210, 212 can be written as

$$I = \frac{{k}^{′}}{2} {( Vgs - Vth )}^{2} . \qquad ( 2 )$$

Thus, the current through resistor R1 202 can be found to be

$$\begin{matrix}I = \frac{Vdd}{R} - \frac{1}{R} ( α \sqrt{I} + Vth ) \\ where α = \sqrt{\frac{2}{{k}^{′}}} .\end{matrix} \qquad ( 3 )$$

In order to find the current sensitivity to the power supply, a partial derivative can be performed and it can be found to be

$$\frac{\partial I}{\partial Vdd} = \frac{1}{R} ( \frac{2 R \sqrt{I}}{2 R \sqrt{I} + α} ) = \frac{1}{R} ( \frac{2 R \sqrt{I}}{2 R \sqrt{I} + \sqrt{\frac{2}{{k}^{′}}}} ) \qquad ( 4 )$$

From this simple analysis, one concludes that in order to get good power supply rejection, the resistance of the bias resistor has to be relatively big. In other words, to design a VCO with resistor bias current source and to obtain good supply pushing, the resistance of the bias resistor 202 has to be increased.

For comparison purposes, two CMOS VCOs as shown in FIG. 2 and FIG. 3 and that have almost the same operation conditions have been built and simulated by the present inventors. The parameters used for simulations are summarized in the Table 1 below.

TABLE 1
Parameters used in simulation for phase noise comparison
between the prior art and embodiments of the present invention.

| Parameters | Value used |
|---|---|
| Inductor Q | 20 |
| Capacitor Q | 40 |
| Differential inductance (nH) | 1.3 |
| Differential capacitance (pF) | 1.35 |
| Cross-coupled transistor sizes (M3-M4) | 8 (2 um/0.2 um) |
| M5 | 60 (20 um/5 um) |
| M1 | (20 um/2 um) |
| M2 | 10 (20 um/2 um) |
| R1 | 1.39 kΩ |
| Vdd | 2.7 V |
| Differential capacitive load | 375 fF |

The simulated results of the two VCOs are summarized in Table 2 below.

TABLE 2
Performance comparison between the prior art VCO in FIG. 2
and the embodiment shown in FIG 3.

| Comparison parameters | Prior art in FIG. 2 | Embodiment in FIG. 3 |
|---|---|---|
| Bias current (mA) | 1.504 | 1.508 |
| Highest voltage swing (mV) | 771.520 | 772.077 |
| Lowest voltage swing (mV) | 435.404 | 434.965 |
| Peak-to-peak voltage (mV) | 336.117 | 337.148 |
| Center frequency (GHz) | 3.41371 | 3.41369 |
| Phase noise @ 1 kHz | −56 dBc/Hz | −58 dBc/Hz |
| Supply pushing (MHz/V) | 3.7 | 3.3 |

Both VCOs have been properly biased and each consumes about 1.5 mA of current. The single-ended peak-to-peak voltage swing is about 336 mV and the center frequency of both oscillators is about 3.4 GHz. The prior art in FIG. 2 shows 2 dB higher phase noise at 1 kHz offset compared to the embodiment shown in FIG. 3. From the noise summary, the main contribution of phase noise at 1 kHz offset frequency originates from the flicker noise of the current source. One can reduce the flicker noise from the current source by using huge transistor sizes. By changing the transistor M1-M2 sizes such that they are 100 times bigger, the simulation results show that one embodiment of the present invention using a resistor bias current source is still better than the prior art. An area-efficient VCO can therefore be realized using the inventive principles set forth herein.

The above phase noise simulation assumes that the reference bias current IB is an ideal current source. If a non-ideal reference current source were used, the phase noise of the VCO will become worse since the noises from the reference current source will be multiplied by the ratio of the current mirror. Thus, using a resistor as a current bias to replace the prior art current source, a lower-current, area-efficient and flicker noise free bias VCO can be implemented. The foregoing simulation was not optimized for very low phase noise at low offset frequency. By proper design and optimization, the embodiments described herein can be found to have promising results.

Another important design parameter for VCOs is supply pushing. This is because for a system-on-chip (SOC) approach, a clean supply for the VCO is very difficult to achieve. The simulation results show that the present inventive embodiments have better supply pushing than that achievable using prior art techniques. By proper design, experimental results by the present inventors have shown that a resistor bias VCO in the preferred embodiment can achieve supply pushing of 1.5 MHz/V.

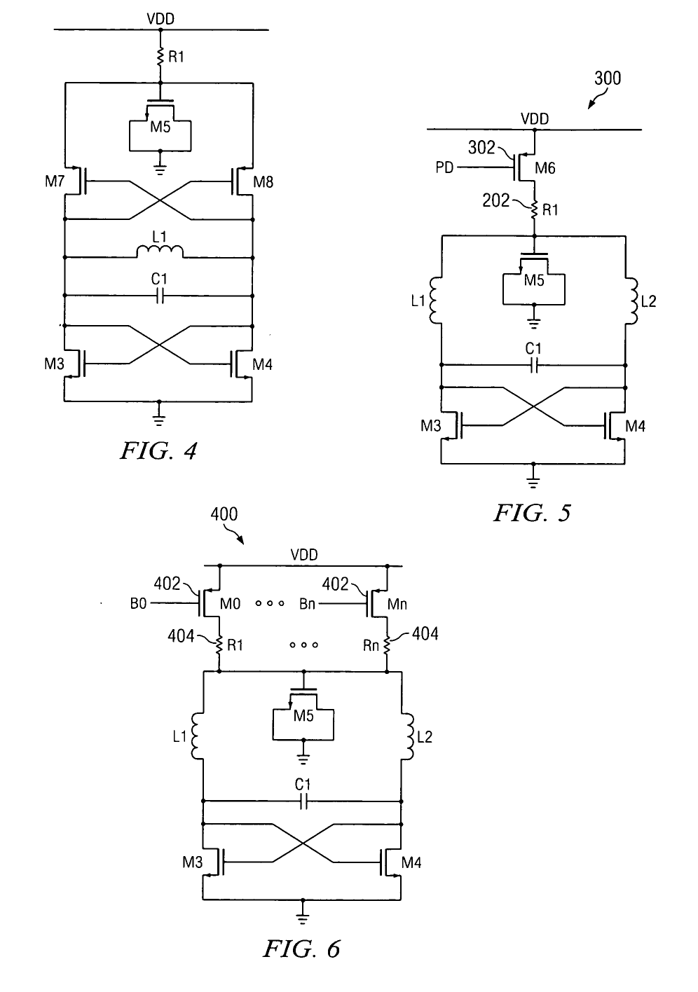

In summary, the preferred embodiment shows good performances in phase noise at low offset frequency, low supply pushing, lower area and lower current consumption compared to that achievable using prior art techniques. The present inventors believe the inventive embodiments described herein should exhibit nearly identical performance if one were to move the bias resistor R1 202 and connect it between the sources of the cross-coupled transistors and ground and connect the center taps of inductors L1-L2 to the VDD supply. One can also use a PMOS cross-coupled pair instead of the NMOS cross-coupled pair or CMOS cross-coupled pairs such as shown in FIG. 4.

Power down capability of a building block is usually a very important function in a system-on-chip design. FIG. 5 illustrates one embodiment 300 to add a power down option by adding an additional transistor M6 302 in series with resistor R1 202. By controlling the gate of the transistor M6 302, the VCO can be either turning off or on. Since transistor M6 302 is in its linear region during operation, any flicker noise contribution is insignificant. The gate to source capacitance of M6 302 can advantageously also provide some decoupling between the power supply and ground.

Another capability that many VCO designers desire is current programmability. Since the present invention employs a resistor as a current source to the VCO core, one can implement a programmable current source 400 such as shown in FIG. 6 simply by paralleling a plurality of resistors 404. By turning the control bits at the gate of PMOS transistors MO-Mn 402 either on or off, the bias current to the VCO core can be easily programmed.

In view of the above, it can be seen the present invention presents a significant advancement in the art of voltage control oscillator design. This invention has been described in considerable detail in order to provide those skilled in the VCO art with the information needed to apply the novel principles and to construct and use such specialized components as are required. In view of the foregoing descriptions, it should be apparent that the present invention represents a significant departure from the prior art in construction and operation. However, while particular embodiments of the present invention have been described herein in detail, it is to be understood that various alterations, modifications and substitutions can be made therein without departing in any way from the spirit and scope of the present invention, as defined in the claims which follow.

What is claimed is:

1. A voltage control oscillator (VCO) comprising:
an L-C tank circuit;
a negative resistance generator operational to oscillate at a frequency determined by the L-C tank circuit, the L-C tank circuit and the negative resistance generator together forming a VCO core; and
a VCO core current source comprising at least one passive resistor, and devoid of capacitors, inductors and active components.

2. The VCO according to claim 1, wherein the negative resistance generator comprises at least one pair of cross-coupled CMOS transistors.

3. The VCO according to claim 1, further comprising a CMOS transistor configured to act as a capacitor and to provide filtering of VCO power supply noise.

4. The VCO according to claim 1, further comprising a CMOS transistor in series with the at least one passive resistor, and operational to selectively turn the VCO core on and off.

5. The VCO according to claim 1, further comprising a CMOS transistor in series with each of the at least one passive resistors, wherein the series CMOS transistors together are configured to selectively control the VCO core bias current.

6. A voltage control oscillator (VCO) comprising:
a tuning circuit;
a negative resistance generator operational to oscillate at a frequency determined by the tuning circuit, the tuning circuit and the negative resistance generator together forming a VCO core; and
a VCO core current source comprising at least one passive resistor, and devoid of capacitors, inductors and active components, wherein the current source operates to provide a VCO bias current.

7. The VCO according to claim 6, wherein the tuning circuit comprises an L-C tank circuit.

8. The VCO according to claim 6, wherein the negative resistance generator comprises at least one pair of cross-coupled CMOS transistors.

9. The VCO according to claim 6, further comprising a CMOS transistor configured to act as a capacitor and to provide VCO bias current noise filtering.

10. The VCO according to claim 6, further comprising a CMOS transistor in series with the at least one passive resistor, and operational to selectively turn the VCO core on and off.

11. The VCO according to claim 6, further comprising a CMOS transistor in series with each of the at least one passive resistors, wherein the series CMOS transistors together are configured to selectively pass a bias current through its respective passive resistor to control the VCO core bias current.

12. A voltage control oscillator (VCO) comprising:
oscillating means for oscillating at a desired frequency;
tuning means for controlling the desired frequency, the oscillating means and the tuning means together forming a VCO core;
biasing means for providing a VCO core bias current, wherein the biasing means is devoid of capacitors, inductors and active components.

13. The VCO according to claim 12, wherein the oscillating means comprises a negative resistance generator.

14. The VCO according to claim 12, wherein the oscillating means comprises at least one pair of cross-coupled CMOS transistors.

15. The VCO according to claim 12, wherein the tuning means comprises a tank circuit.

16. The VCO according to claim 15, wherein the tank circuit is an L-C tank circuit.

17. The VCO according to claim 12, wherein the biasing means comprises a single passive resistor.

18. The VCO according to claim 17, further comprising at least one CMOS transistor configured to act as a capacitor and to provide filtering of VCO power supply noise.

19. The VCO according to claim 17, further comprising a CMOS transistor in series with the single passive resistor, and operational to selectively turn the VCO core on and off.

20. The VCO according to claim 12, wherein the biasing means comprises a plurality of passive resistors.

21. The VCO according to claim 20, further comprising a CMOS transistor in series with each passive resistor, wherein the series CMOS transistors together are configured to selectively activate the passive resistors to control the VCO core bias current.

22. A method of controlling a voltage control oscillator (VCO) phase noise, the method comprising the steps of:
providing a VCO core; and
generating a self-bias current for the VCO core via a resistor bias current source that is devoid of capacitors, inductors and active components.

23. The method according to claim 22, further comprising the steps of:
providing means for programming the resistor bias current source; and
programming the resistor bias current source to selectively control the bias current to the VCO core.
